(19) United States
(12) Patent Application Publication
(10) Pub. No.: US 2011/0156240 A1
(43) Pub. Date: Jun. 30, 2011

(54) RELIABLE LARGE DIE FAN-OUT WAFER LEVEL PACKAGE AND METHOD OF MANUFACTURE

(75) Inventors: Jing-En Luan, Singapore (SG); Kim-Yong Goh, Singapore (SG)

(73) Assignee: STMICROELECTRONICS ASIA PACIFIC PTE. LTD., Singapore (SG)

(21) Appl. No.: 12/651,362

(22) Filed: Dec. 31, 2009

(51) Int. Cl. H01L 23/488; H01L 21/78; H01L 21/60

(52) U.S. Cl. 257/692; 438/113; 438/612; 257/737; 257/E21.599; 257/E23.023; 257/E21.509

(57) ABSTRACT

A fan-out wafer level package includes a semiconductor die with contact pads positioned on a top surface. A fan-in redistribution layer positioned over the die includes contact pads in electrical communication with the first contact pads of the die. A buffer layer positioned over the fan-in layer includes a plurality of vias, in electrical contact with the contact pads of the fan-in layer. A fan-in redistribution layer is positioned over the buffer layer and includes contact pads on a surface opposite the buffer layer, in electrical communication with the vias. The semiconductor die, fan-in layer, and buffer layer are encapsulated in a molding com-pound layer. Solder contacts, for electrically connecting the semiconductor device to a electronic circuit board, are positioned on contact pads of the fan-out layer. The buffer layer has a substantial thickness, to reduce and distribute shear stresses resulting from thermal mismatch of coefficients of thermal expansion of the semiconductor die and a circuit board.

### BACKGROUND OF THE INVENTION

1. Technical Field

Disclosed embodiments of the invention are directed to fan-out wafer-level semiconductor device packages, and in particular, to fan-out packages for very large semiconductor dies, which are less subject to failure of redistribution layers or solder joints because of thermal mismatch or misalignment of redistribution layers.

2. Description of the Related Art

For manufacturers of semiconductor devices, there is a continuing pressure to increase the density and reduce the size of the devices, so that more devices can be made on a single wafer of semiconductor material, and so that products that incorporate the devices can be made more compact. One response to this pressure has been the development of chip scale packaging and wafer level packaging. These are packages that have an area that is very close to the area of the semiconductor die. They are generally direct surface mountable, using, e.g., ball grid arrays and flip chip configurations.

Until the development of mounting structures such as ball grid arrays on flip chips, connections to semiconductor dies were most commonly made around the perimeter of a die, by wirebonding, for example. As a result, most semiconductor devices were designed with contact pads positioned at the edges of the active surfaces of the dies. In order to reconfigure an existing design for a ball grid array, an additional redistribution layer is typically added to the design. This layer is deposited over an otherwise completed wafer of dies, and includes conductive traces that are electrically coupled at one end to respective contact pads around the perimeter of each die, and at the other end to contact pads that are repositioned laterally on the surface of the wafer, generally in a more even distribution over the surface of the die. in this way, the pitch of the contact pads can be reduced, simplifying the formation of the solder balls on the dies, as well as improving the reliability of a solder bond with a circuit board, when a die is installed. This layer is sometimes referred to as a fan-in layer.

FIG. 1 shows an exemplary fan-in pattern of traces 52 of a redistribution layer 50, according to known technology. Each trace 52 extends from a perimeter contact pad 54 of the underlying die 58 to one of an array of a solder ball contact pads 56. It can be seen that the pitch of the array of pads 56 is significantly larger, as compared to that of the original pads 54. Another development in semiconductor packaging is the reconfigured wafer, in which a semiconductor wafer is separated into dies, which are reformed into a “reconfigured wafer” in which the dies are spaced some greater distance apart, after which additional processing steps are performed on the devices. One benefit is that this provides increased area for each die for “back end” processes, such as the formation of contacts at a scale or pitch that is compatible with circuit board limitations, without sacrificing valuable real estate on the original wafer. Such a package is sometimes referred to as a fan-out package, because the contact positions of the original die are “fanned out” to a larger foot print. A prior art method of manufacturing a fan-out package 100 is briefly outlined with reference to FIGS. 2-5. Hereafter, the top of a semiconductor device is to be understood as referring to the side of a semiconductor wafer or die on which the active device is formed.

As shown in FIGS. 2 and 3, dies 102 of a parent wafer are individually positioned with their top sides facing a laminate carrier strip 104, and held in position by an adhesive tape 106. A liquid molding compound is deposited over the dies 102 and subjected to a compression molding process during which the compound is cured into a hard layer 110—the molding compound is similar to the epoxy material commonly used to form conventional semiconductor packages.

After curing, the laminate carrier strip 104 and tape 106 are removed, leaving the layer 110, in which the original dies 102 are embedded, with a active surface 112 in which the top, or active, surfaces 114 of the dies are exposed for additional processing, as shown in FIG. 4. A redistribution layer 116 is then formed on the layer 110, as shown in FIG. 5.

To form the redistribution layer 116, a dielectric layer 118 is deposited over the active surface 112 and patterned to provide apertures over contact pads 120 of the original dies 102. A conductive layer is then deposited and patterned to fill the apertures and form electrical traces 122. A second dielectric layer 124 is deposited and patterned to form apertures over contact regions of the electrical traces 122, and a final conductive layer 126 is deposited and patterned to form redistributed contact pads 128 over the apertures in the second dielectric layer. Solder balls 130 are formed on the contact pads 128, and the layer 110 is cut at lines K, which define a saw kerf, to produce individual fan-out wafer level packages 100.

Fan-out wafer level packages of the kind described with reference to FIGS. 2-5 typically have a large number of solder contacts distributed across a face of the package. The package is positioned on a circuit board, with each of the solder balls in physical contact with a corresponding contact pad of an underlying circuit board. The solder balls are then heated to a temperature that is above the melting temperature of the solder, thereby melting the solder balls so that they reflow and form electrical and mechanical joints between the respective contact pads of the semiconductor package and the circuit board.

During operation of semiconductor devices of the kind discussed above, it is typical for such a device to generate a significant amount of heat. The large number of solder ball joints that couple the device to a circuit board provide a beneficial heat sink function, by conducting heat from the device to the circuit board, where it can be drawn away. Nevertheless, during normal operation, both the semiconductor device and the circuit board immediately adjacent to the device may heat to 60-70° C. above ambient, only cooling after the device is shut down.

Currently, the number of dies that can be assembled together in a reconfigured wafer is limited because of difficulties associated with precise positioning of the individual dies on the laminate by reference to relative spacing alone. With larger numbers it becomes increasingly difficult to position them with sufficient accuracy to prevent misregistration of the etch masks of the redistribution layer, which results in misalignment of the layer.

### BRIEF SUMMARY

According to an embodiment of the invention, a fan-out wafer level package is provided, comprising a semiconductor die including a first plurality of contact pads positioned on an active surface thereof. A first redistribution layer is positioned over the active surface of the semiconductor die and includes a second plurality of contact pads, each in electrical communication with a respective one of the first plurality of contact pads. A buffer layer is positioned over active surface of the first redistribution layer and includes a plurality of vias, each in electrical contact with a respective one of the second plurality of contact pads and having, at a surface of the buffer layer, a respective one of a third plurality of contact pads in electrical communication with the respective one of the second plurality of contact pads. The buffer layer has a thickness that is at least twice a thickness of the first redistribution layer, and may have a thickness that is in the range of 10-100 times thicker than the first redistribution layer.

The first redistribution layer and buffer layer are formed on the active semiconductor wafer before it is singulated and are cut apart when the parent wafer is cut. They are therefore coextensive with the semiconductor die along axes parallel to the first surface of the semiconductor die. The first redistribution layer is a fan-in layer that enlarges the pitch of the contacts.

a second redistribution layer is positioned over the active surface of the buffer layer and includes a fourth plurality of contact pads positioned on a surface of the second redistribution layer, each in electrical communication with a respective one of the third plurality of contact pads, and arranged in a fan-out pattern. A plurality of solder contacts, for electrically connecting the semiconductor device to a electronic circuit board, is positioned on respective ones of the fourth plurality of contact pads, and an encapsulating layer is positioned on a bottom surface of the second redistribution layer and encapsulates the semiconductor die, the first redistribution layer, and the buffer layer.

### BRIEF DESCRIPTION OF THE SEVERAL VIEWS OF THE DRAWINGS

FIG. 1 shows an exemplary fan-in pattern of a redistribution layer according to known technology.

FIGS. 2-5 illustrate respective stages of a prior art method of manufacturing a fan-out package.

FIG. 6 is a diagrammatic cross-sectional view of a fan-out wafer level semiconductor package according to an embodiment of the invention.

FIGS. 7-14 show the semiconductor package of FIG. 6 at succeeding stages of manufacture, all shown as diagrammatic cross sections.

FIG. 15 shows a fan-out package according to another embodiment.

### DETAILED DESCRIPTION

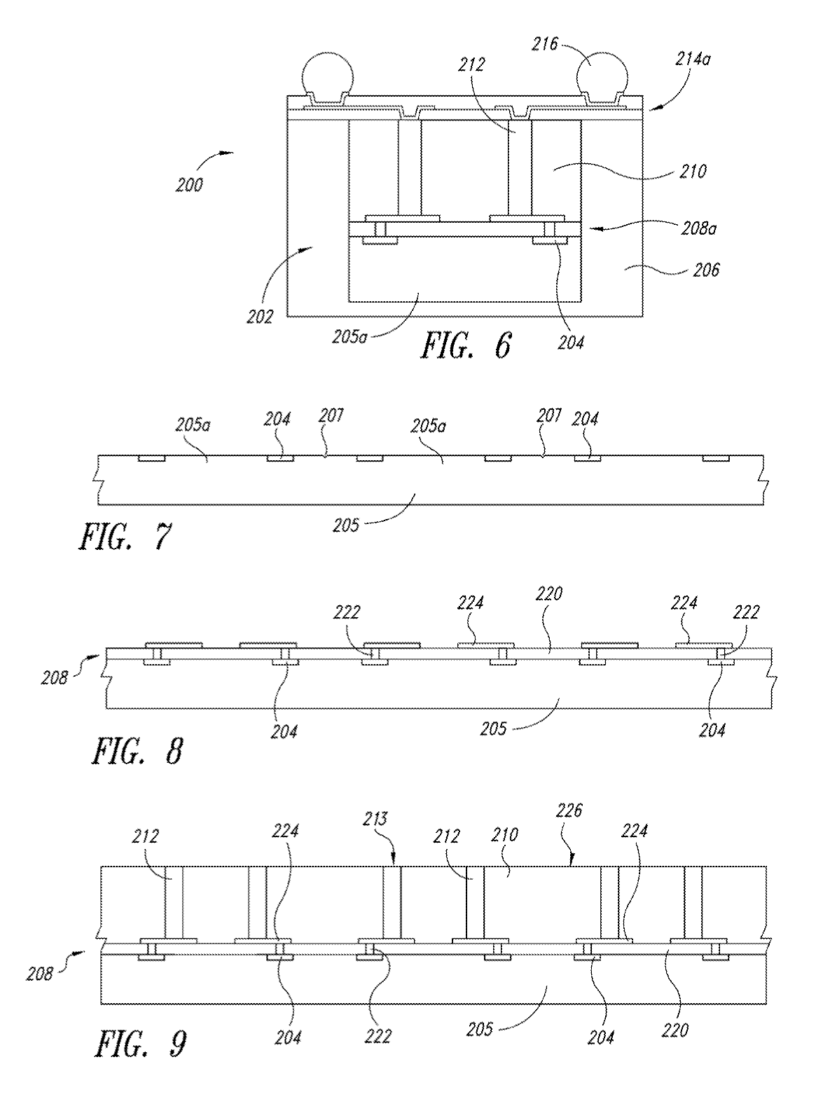

FIG. 6 shows a fan-out wafer level semiconductor package 200 according to an embodiment of the invention. The package 200 includes a die assembly 202 encapsulated in a molding compound casing 206, a redistribution layer 214a positioned on one face thereof, and a plurality of solder balls 216. The die assembly 202 comprises a semiconductor die 205a with a plurality of contact pads 204, a fan-in redistribution layer 208a, and a buffer layer 210. Conductive vias 212 extending in the buffer layer 210 provide electrical coupling between conductive traces in the fan-in redistribution layer 208a and the fan-out redistribution layer 214a. A process for manufacturing the semiconductor package 200 of FIG. 6 will now be discussed with reference to FIGS. 7-14.

FIG. 7 shows a portion of a wafer 205 on which is formed a plurality of individual semiconductor dies 205a that are manufactured according to known methods. Each die 205a is separated from other dies 205a by a scribe line 207 as is known in the art. Contact pads 204 are provided on an active surface of the wafer 205 for electrical communication with each semiconductor die 205a formed thereon.

FIG. 8 shows the wafer 205 with a fan-in redistribution layer 208 formed on the active surface. The redistribution layer 208 is formed in accordance with known methods, such as described above, for example, with reference to FIG. 5. The redistribution layer 208 shown in FIG. 8 includes a dielectric layer 220 in which a plurality of apertures are formed in positions corresponding to respective ones of the plurality of contact pads 204 on the active surface of the wafer 205. The apertures are filled with a conductive material, e.g., aluminum, tungsten, copper alloy, or the like, that forms a via 222 that extends from the respective contact pads 204 on a lower side of the dielectric layer 220 to an upper side of the dielectric layer. An electrically conductive layer is formed over the dielectric layer 220 and is etched to leave conductive traces 224 in electrical contact with the vias 222 and providing contact surfaces on the upper side of the dielectric layer 220.

As shown in FIG. 9, a dielectric buffer layer 210 is formed on the upper surface of the dielectric layer 220. To form the buffer layer 210, a layer of photosensitive material is first deposited on the upper surface of the dielectric layer 220, and patterned, according to well known procedures, to form a plurality of apertures 210 in the layer, positioned over contact surfaces of the electrical traces 224, and extending the thickness of the layer. Preferably, the layer of photosensitive material is a curable polymer that can be hardened, either during the exposure and developing process, or during a later stage, to form a durable layer. Conductive vias 212 are next formed in the apertures in electrical contact with the electrical traces 224 by any appropriate process, including electroplating, chemical vapor deposition, etc. To complete the dielectric buffer layer 210, an upper surface of the layer of photosensitive material is planarized to provide a flat upper surface 226. Upper faces of the vias 212 act as contact pads 213.

In comparison to a thickness of the redistribution layer 208, the buffer layer 210 is substantially thicker. For example, the redistribution layer 208 may have a total thickness of between 0.3 μm (micro-meters) and about 7 μm, while the buffer layer may have a thickness of between around 10 μm and around 200 μm. According to another embodiment, the thickness of the buffer layer can be selected from within a range of about 20 μm to about 150 μm. The thickness of the buffer layer 210 may be related, in part, to the overall dimensions of the die 205a over which it is positioned, as well as other factors, which will be discussed later. A diameter or width of the conductive vias 212 is selected, in part, to adequately conduct heat from the semiconductor die 205a to the upper surface 226.

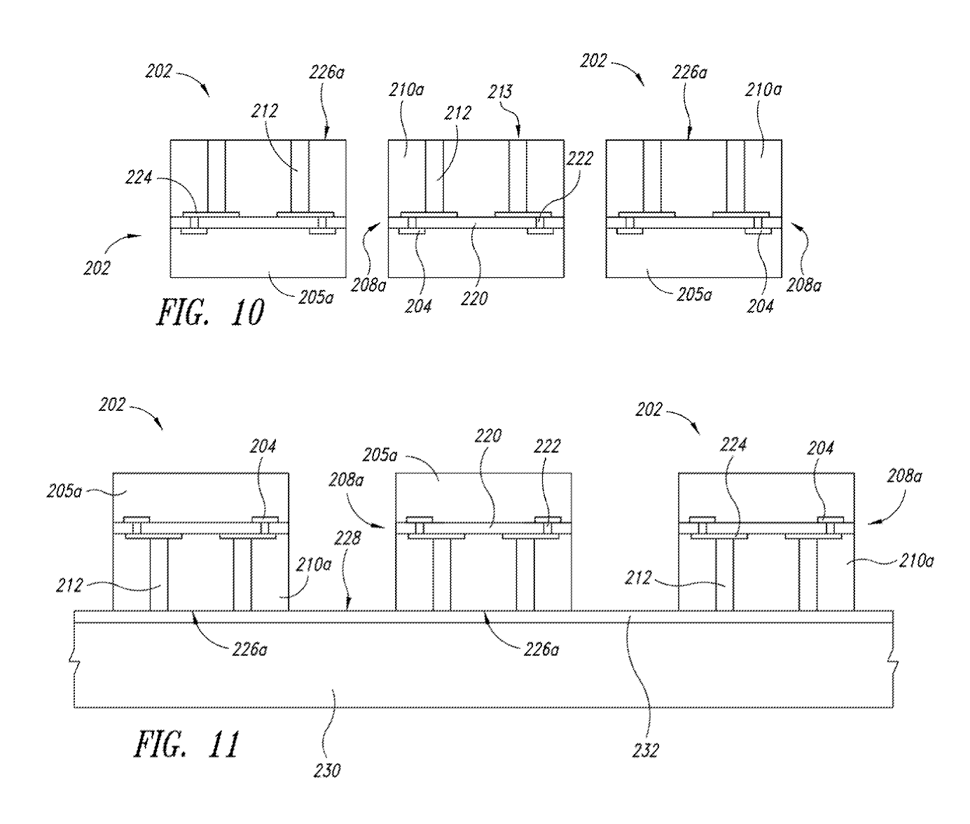

Turning now to FIG. 10, the wafer 205 is next separated into individual dies 205a, each including a portion 208a of the redistribution layer 208 and a portion 210a of the buffer layer 210 with a respective upper surface 226a, all of these elements together forming a die assembly 202.

As shown in FIG. 11, a carrier substrate 230 is provided with an adhesive tape 232 positioned thereon and having a surface 228. Each of the die assemblies 202 is positioned with its respective upper surface 226a in contact with the surface 228 of the adhesive tape 232, where it is held in position by the tape.

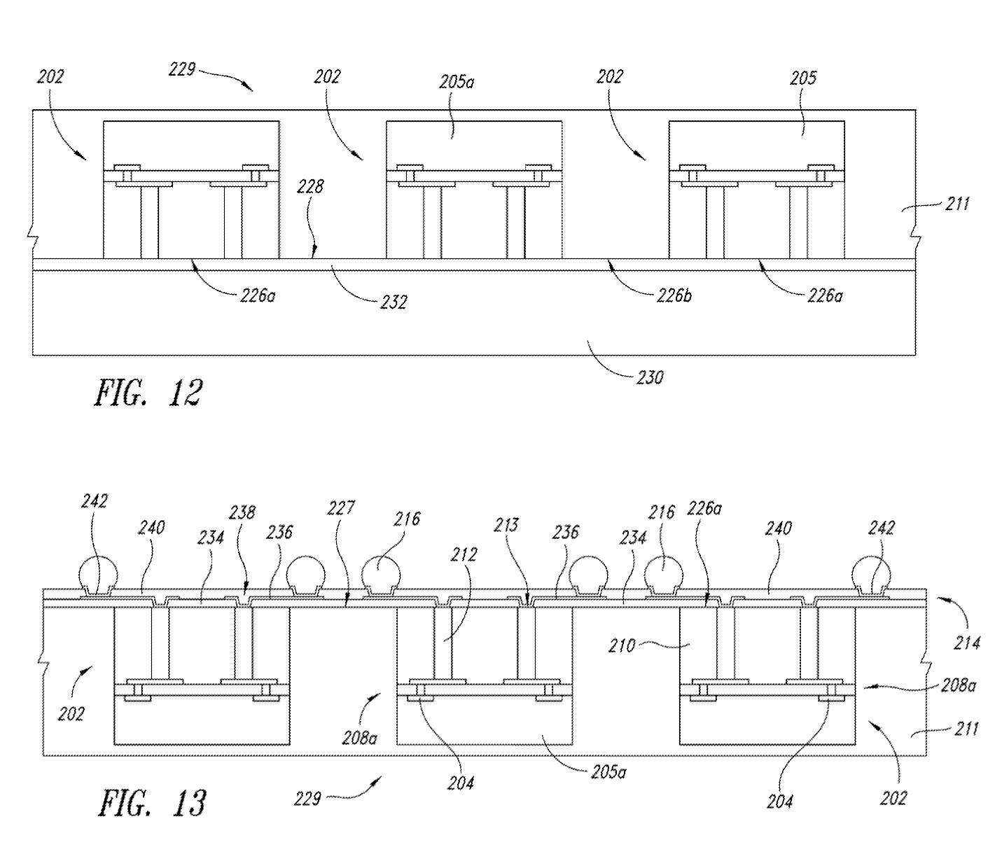

As shown in FIG. 12, an encapsulating layer 206 is formed over the carrier laminate 230 and the attached die assemblies 202. According to one embodiment, a liquid molding compound 211 is deposited over the surface 228 of the carrier laminate 230 and adhesive tape 232, and subjected to a compression molding process, which hardens the molding compound, thereby encapsulating the die assemblies 202 in the encapsulating layer 206. A reconfigured wafer 229 is thereby formed, having a continuous upper surface 227 that comprises the upper surfaces 226a of each of the die assemblies 202. After formation of the encapsulating layer 206, the carrier laminate 230 and adhesive tape 232 are removed from the wafer 229, exposing the upper surface 227 of the reconfigured wafer 229.

The die assemblies 202 are spaced farther from each other in the reconfigured wafer 229 than were the dies 205a in the original wafer 205. The same number of dies 205a therefore take up more area, and so the reconfigured wafer, if it has the same number of dies 205a, will be larger than the original wafer 205. The reconfigured wafer can have more or fewer dies 205a, by either combining dies 205a from a number of wafers 205 or by only having some of the dies 205a from the wafer 205, respectively. The recombined wafer can be any shape, such as square, rectangular, round, etc.

As shown in FIG. 13, a fan-out redistribution layer 214 is formed on the upper surface 227 of the reconfigured wafer 229 in accordance with known principles. The redistribution layer 214 shown in FIG. 13 includes a first dielectric layer 234 with apertures formed therein in positions corresponding to the contact pads 213 of the die assemblies 202, a conductive layer formed on an upper surface of the first dielectric layer 234 and comprising a plurality of electrically conductive traces 236 extending into the apertures 238 to make electrical contact with the vias 212. A second dielectric layer 240 is formed or positioned over the first dielectric layer 234 and the electrical traces 236. The second dielectric layer 240 also includes a plurality of apertures, each positioned over a contact region of a respective one of the electrical traces 236. A final layer of conductive material is deposited over the second dielectric layer 240 and patterned to form a plurality of contact pads 242 over respective ones of the apertures in the second dielectric layer, and making contact with the respective electrical traces 236. Finally, solder ball contacts 216 are formed on each of the contact pads 242.

Referring again to FIG. 13, it can be seen that the process described above provides a continuous electrical connection from each of the contact pads 204 of the semiconductor dies 205a to respective ones of the solder balls 216. The fan-in configuration of the first redistribution layer 208a contacts each of the contact pads 204, which may be distributed with very close pitch spacing, and places the contact pads in electrical contact with the vias 212 at a much larger pitch. Because the first redistribution 208 is formed on the surface of the original wafer 205 before the wafer is cut into individual dies and reconfigured, the registration of the masks used to form the first redistribution layer 208 does not present any difficulties. Conversely, where mask registration over a reconfigured wafer is normally particularly challenging because the individual dies have been repositioned, the enlarged pitch of the vias 212 and contact pads 213 of the die assemblies 202 simplifies registration of the masks of the second redistribution layer 214, and enables reconfiguration of larger individual devices into a single wafer.

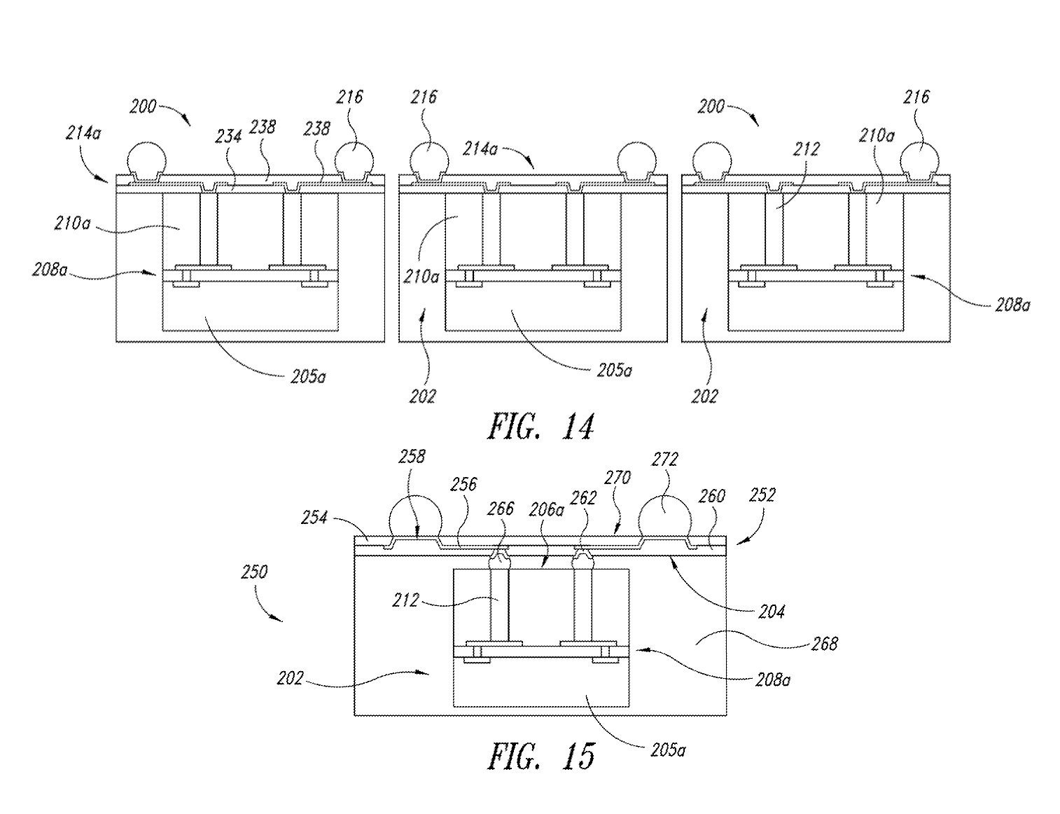

As shown in FIG. 14, the reconfigured wafer 229 is singulated to produce a plurality of fan-out wafer level packages 200. These packages require no further processing, but are in condition to be installed in a circuit.

FIG. 15 shows a fan-out package 250 according to another embodiment. A die assembly 202 is coupled to contact pads 262 of a fan-out layer 252 by solder contacts 266. An encapsulating layer 268 encapsulates the die assembly 202 and the solder contacts 266 in a manner similar to that described above. A detailed disclosure of a method of manufacture of such a device is provided in the co-pending application titled, “Flip-chip fan-out wafer level package for package-on-package applications, and a method of manufacturing,” filed in the name of the inventors of the presently disclosed invention, and filed concurrently herewith, which application is hereby incorporated by reference, in its entirety.

There are a number of benefits associated with the principles of the invention, especially with regard to fan-out packages for semiconductor dies that are larger than about four or five millimeters on a side. Previously, reliability of a fan-out package has been inversely related to the size of the semiconductor die, generally because of either of two problems: misalignment of the etch masks of the redistribution layer, or failure of the solder joints where the package is attached to a circuit board.

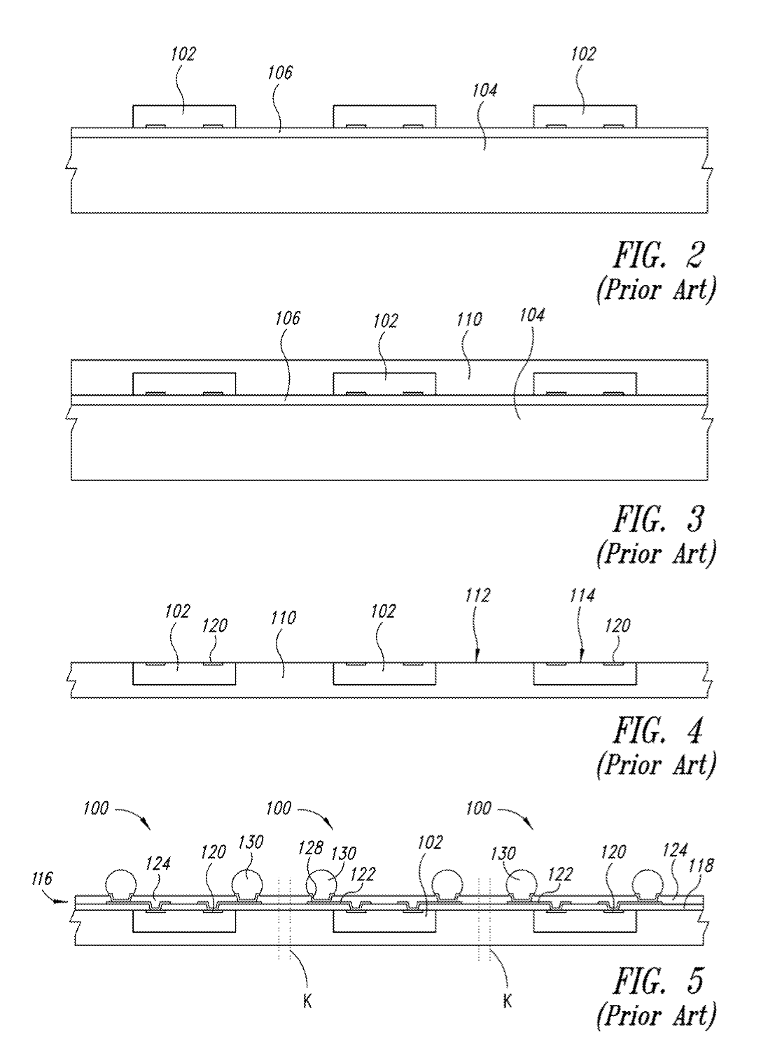

The first of these problems arises because of limitations in the formation of the prior art reconfigured die, as described above with reference to FIGS. 2-4. The dies must be positioned with sufficient precision that when the redistribution layer 116 is formed on the reconfigured wafer, every contact pad 120 of every die 102 is positioned precisely as necessary to be coupled by the conductive traces 122 to the solder balls 130. The dies are positioned on the laminate carrier by automatic equipment in a “pick-and-place” operation. The equipment is capable of very high precision, but because there are no previously formed features on the laminate carrier 104 or the adhesive tape 106 to which the dies can be registered, they are positioned solely on the basis of their position relative to some reference point. Because of normal design tolerances of the equipment, resiliency of the adhesive tape, and other environmental influences, each die can have a small variation in position. From one die to the next, these variations are generally within acceptable limits, but over greater distances, the variations can compound. Across a large number of dies, or a smaller number of large dies, it becomes increasingly difficult to adjust the masks to compensate for the accumulated changes in location in one direction while also accommodating changes in locations of the dies in the opposite direction. Accordingly, the size of the laminate carrier 104 in the prior art must be limited to avoid building up too large an accumulated error in the location of the contact pads 120. Thus, as die size increases, the numbers of dies per reconfigured wafer decreases, which drives up the production cost per die.

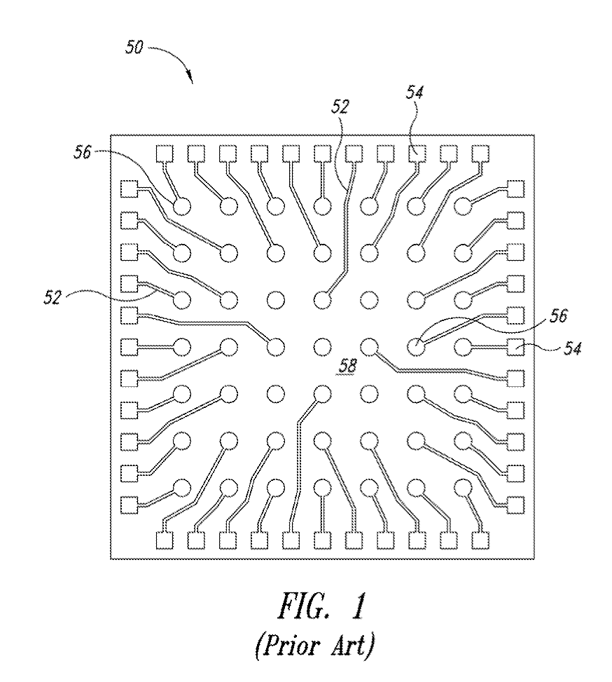

This problem is addressed in the disclosed embodiments by the first redistribution layer 208 described with reference to FIG. 8. This layer is deposited before the wafer is singulated into individual dies. Thus, there are none of the problems associated with repositioning the dies. While the very close pitch of the contact pads of each die may be extremely tight in the context of a reconfigured wafer, it is not particularly tight with respect to the equipment used for forming layers on the original wafer 205. The fan-in pattern of the first redistribution layer 208 redistributes the contact pads to a much larger pitch, as illustrated in the example of a fan-in layer described with reference to FIG. 1. As employed in the prior art, the fan-in redistribution layer is used to accommodate solder balls, for a flip chip package, for example. The larger pad separation of the redistribution layer permits formation of solder balls that are large enough to couple the device to a circuit board, without flowing together.

As used according to the principles of the invention, the larger pitch provided by the first redistribution layer enables larger dies to be reconfigured in higher quantities. The larger pitch permits the use of a larger design rule at later steps. Referring again to the fan-in pattern shown in FIG. 1, given the pitch and size of the original contact pads 54, any feature intended to contact a single one of the pads 54 cannot be much larger than the pads themselves, and must be positioned with sufficient accuracy that it does not fall to one side of the pad or create a short circuit to an adjacent pad. In contrast, a feature intended to contact one of the pads 56 of the redistribution layer has much more leeway with respect to size and accuracy of position. The feature can be much larger than the pad 56, which in turn permits greater deviation from a perfectly aligned position while still maintaining electrical contact and avoiding a short with an adjacent pad. Thus, the tolerances for positioning of the die assemblies 202 on the carrier laminate 230, for formation of the reconfigured wafer 229, and eventual formation of the second redistribution layer 214, are greater than those of the prior because of the fan-in redistribution layer 208.

Because the vias 212 of all of the dies 205a are formed simultaneously, before the wafer 205 is singulated, deviations of position relative to the contact surfaces of the redistribution layer 208 will be identical on the surface 226a of each die assembly 202. This means that on the surface 227 of the reconfigured wafer 229, the relative positions of the contact pads 213 of each of the die assemblies 202 will be no less accurate than would be the positions of the contact surfaces of the respective portions 208a of the redistribution layer if the buffer layer 210 were not present. Thus, alignment of the second redistribution layer 214 is not made more difficult by the presence of the buffer layer 210. Furthermore, the larger pitch of the contact surfaces of the conductive traces 224 permits the formation of larger vias 212, which serve to more efficiently conduct heat from the semiconductor die 205a to the circuit board.

In embodiments where the pitch of the first plurality of contact pads 204 on the die 205a is acceptably large, the first redistribution layer 208 can be omitted, and the buffer layer 210 formed with the vias contacting the first plurality of contact pads directly.

The second problem arises because of the thermal cycling that each device experiences during normal operation. As noted above, a semiconductor device and circuit board regularly undergo thermal cycles of heating and cooling that can be as wide as 70° C. With each heating cycle, the material of the semiconductor device and package, and the adjacent circuit board, undergo thermal expansion, and then contract again as the device cools. In cases where the die of the semiconductor device is larger than around 5 or 6 millimeters on a side, thermal mismatch can produce significant stress on the solder joints. Where silicon has a coefficient of thermal expansion (CTE) of around 2.6 ppm/° C., a circuit board can have a CTE of anywhere from around 16 ppm/° C. to around 50 ppm/° C., and in some cases higher. This means that with each thermal cycle, the solder joints undergo shear stresses as the circuit board expands relative to the semiconductor die. Furthermore, the degree of stress increases as the size of the die increases. In models run by the inventor, in a conventional fan-out package with a die of about 6 mm×6 mm, at least one of the solder joints experienced shear stresses that exceeded the maximum acceptable stress by about 50%, meaning that such a joint would probably fail prematurely. In contrast, in models of packages configured according to the disclosed principles of the invention, under otherwise identical conditions, the maximum stress experienced by any of the solder joints was about half the maximum acceptable stress.

The reduction in shear stress is produced by the buffer layer described with reference to FIG. 9, which acts to distribute the shear stress across an increased vertical distance, thereby reducing the concentration of stress at the solder joints. Essentially, the polymeric material of the buffer layer is less rigid than the silicon of the semiconductor die, so it can conform to some degree with the expansion of the circuit board on one side while also conforming to the semiconductor die on the other. Of course, this capacity to conform will be directly related to the thickness of the buffer layer. a thick buffer layer will be able to conform to a greater degree than a relatively thinner one. Thus, as noted above, the thickness of the buffer layer can be selected according to a number of factors, which are generally related to the degree of conformance that will be required. These factors can include, for example, the largest lateral dimension of the semiconductor die, the number and size of solder contacts over which shear stress will be distributed, the relative coefficients of thermal expansion of the circuit board and the semiconductor die, and the normal and maximum acceptable operating temperatures of the semiconductor device.

In embodiments in which the thermal mismatch is acceptably low, the buffer layer can be omitted entirely, and the second redistribution layer positioned directly over the first redistribution layer, thereby reducing a height of the overall device while still providing for an improved alignment of the second layer, and permitting more and/or larger dies in the reconfigured wafer.

Devices that are formed on semiconductor material substrates are generally formed on only one surface thereof, and occupy a very small part of the total thickness of the substrate. This surface is generally referred to as the active surface herein, also referred to as the front side or top side of the wafer. For the purposes of the present disclosure and claims, the terms top and bottom are used to establish an orientation with reference to a semiconductor wafer or die. For example, where a device includes a semiconductor die, reference to a top surface of some element of the device can be understood as referring to the surface of that element that would be uppermost if the device as a whole were oriented so that the active surface of the die was the uppermost part of the die. Of course, a bottom surface of an element is the surface that would be lowermost, given the same orientation of the device. Use of either term to refer to an element of such a device is not to be construed as indicating or requiring an actual physical orientation of the element, the device, or the associated semiconductor component, and, where used in a claim, does not limit the claim except as explained above.

Processes for performing the manufacturing steps discussed above are very well known in the art, and are within the abilities of a person having ordinary skill in the art.

Ordinal numbers, e.g., first, second, third, etc., are used according to conventional claim practice, i.e., for the purpose of clearly distinguishing between claimed elements or features thereof. The use of such numbers does not suggest any other relationship, e.g., order of operation or relative position of such elements. Furthermore, ordinal numbers used in the claims have no specific correspondence to those used in the specification to refer to elements of disclosed embodiments on which those claims read.

The first and second redistribution layers described above are provided as examples, only. In practice, they can be provided with any appropriate number and configuration of dielectric and conductive layers.

The term redistribution layer refers to a layer that includes conductive traces to laterally reposition contact pads of a semiconductor device. The term is sometimes used in the art to refer to a single conductive layer, while at other times it is used so broadly as to refer to any related structure, including support substrates, laminate strips and bases, etc. For the purposes of the present disclosure and claims, redistribution layer is a layer that includes one or more layers of dielectrics and conductors that are formed or deposited on an underlying substrate or layer to create and isolate redistributing signal paths of a semiconductor die, including a die of a reconfigured wafer. Any of the individual layers can themselves comprise multiple layers. For example, the dielectric layers can include one or more passivation layers, insulating layers, etc., and the conductive layers can include one or more interconnect layers, metal layers, seed layers, undermetal layers, plated metallic layers, vapor deposited layers, barrier layers, etc. For the purposes of the present disclosure and claims, the buffer layer is not part of a redistribution layer, because a redistribution layer serves to reposition contact pads in a substantially horizontal direction, while the buffer layer serves to create a vertical separation in the device.

The abstract of the present disclosure is provided as a brief outline of some of the principles of the invention according to one embodiment, and is not intended as a complete or definitive description of any embodiment thereof, nor should it be relied upon to define terms used in the specification or claims. The abstract does not limit the scope of the claims.

The following U.S. patent applications, filed concurrently herewith, are directed to subject matter that is related to or has some technical overlap with the subject matter of the present disclosure: MULTI-STACKED SEMICONDUCTOR DICE SCALE PACKAGE STRUCTURE AND METHOD OF MANUFACTURING SAME, by Kim-Yong Goh, attorney docket No. 851663.488; FAN-OUT WAFER LEVEL PACKAGE FOR AN OPTICAL SENSOR AND METHOD OF MANUFACTURE THEREOF, by Kim-Yong Goh and Jing-En Luan, attorney docket No. 851663.493; FLIP-CHIP FAN-OUT WAFER LEVEL PACKAGE FOR PACKAGE-ON-PACKAGE APPLICATIONS, AND METHOD OF MANUFACTURE, by Kim-Yong Goh and Jing-En Luan, attorney docket No. 851663.494; and FAN-OUT WAFER LEVEL PACKAGE WITH POLYMERIC LAYER FOR HIGH RELIABILITY, by Kim-Yong Goh, attorney docket No. 851663.501; each of which is incorporated herein by reference in its entirety.

Elements of the various embodiments described above can be combined, and further modifications can be made, to provide further embodiments without deviating from the spirit and scope of the invention. All of the U.S. patents, U.S. patent application publications, U.S. patent applications, foreign patents, foreign patent applications and non-patent publications referred to in this specification and/or listed in the Application Data Sheet, are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification, but should be construed to include all possible embodiments along with the full scope of equivalents to which such claims are entitled. Accordingly, the claims are not limited by the disclosure.

1. A device, comprising:
a semiconductor die, including a first plurality of contact pads positioned on a top surface thereof;
a first redistribution layer positioned over the top surface of the semiconductor die and having a second plurality of contact pads, each in electrical communication with a respective one of the first plurality of contact pads; and
a buffer layer positioned over a top surface of the first redistribution layer and having a plurality of vias, each in electrical contact with a respective one of the second plurality of contact pads and having, at a top surface of the buffer layer, a respective one of a third plurality of contact pads in electrical communication with the respective one of the second plurality of contact pads, the buffer layer having a thickness that is at least twice a thickness of the first redistribution layer.

2. The device of claim 1 wherein the thickness of the buffer layer is between about 20 μm and 150 μm.

3. The device of claim 1 wherein the buffer layer is coextensive with the semiconductor die along axes parallel to the first surface of the semiconductor die.

4. The device of claim 1 wherein the first redistribution layer is a fan-in layer.

5. The device of claim 1 wherein the semiconductor die has at least one dimension that is greater than about 5 mm.

6. The device of claim 1, comprising:
a second redistribution layer positioned over the top surface of the buffer layer and including a fourth plurality of contact pads positioned on a top surface of the second redistribution layer, each in electrical communication with a respective one of the third plurality of contact pads, the second redistribution layer having at least one dimension, along an axis parallel to the top surface of the semiconductor die, that exceeds a corresponding dimension of the semiconductor die; and
an encapsulating layer positioned on a bottom surface of the second redistribution layer and at least partially encapsulating the semiconductor die, the first redistribution layer, and the buffer layer, the encapsulating layer being coextensive with the second redistribution layer along axes parallel to the first surface of the semiconductor die.

7. The device of claim 6, comprising a plurality of solder contacts, each positioned on a respective one of the fourth plurality of contact pads.

8. The device of claim 6 wherein the second redistribution layer is a fan-out layer.

9. The device of claim 6 wherein the second redistribution layer comprises a fifth plurality of contact pads positioned on the bottom surface of the second redistribution layer, each in each in electrical communication with a respective one of the fourth plurality of contact pads, the device further comprising a plurality of solder contacts, each extending between and electrically connecting respective ones of the third and fifth pluralities of contact pads.

10. A method, comprising:
forming a first redistribution layer on a top surface of a semiconductor wafer having thereon a first plurality of contact pads, including:
forming a dielectric layer,
forming a plurality of vias, each in electrical contact with a respective one of the first plurality of contact pads, and
forming a plurality of conductive traces over the dielectric layer, each in electrical contact with a respective one of the plurality of vias;
forming, on the first redistribution layer, a buffer layer having a thickness that is at least about twice a thickness of the first redistribution layer;
forming a plurality of vias in the buffer layer, each in electrical contact with a respective one of the plurality of conductive traces and having, at a top surface of the buffer layer, a respective one of a second plurality of contact pads; and
separating the semiconductor wafer into a number of die assemblies, each including portions of the first redistribution layer and the buffer layer.

11. The method of claim 10 wherein a pitch of the first plurality of contact pads is finer than a pitch of the second plurality of contact pads.

12. The method of claim 10, comprising:
forming a reconfigured wafer, including:
affixing a plurality of the die assemblies onto a surface of a carrier substrate, with active surfaces of the die assemblies facing the surface of the carrier substrate,
depositing a liquid encapsulating material on the surface of the carrier substrate;
hardening the encapsulating material to form an encapsulating layer that at least partially encapsulates each of the die assemblies, and
removing the carrier substrate from the die assemblies and the encapsulating layer to expose the top surfaces of the die assemblies at a top surface of the reconfigured wafer; and
forming a second redistribution layer over the top surface of the reconfigured wafer, including forming a third plurality of contact pads, each in electrical contact with a respective one of the second plurality of contact pads.

13. The method of claim 10, comprising forming a plurality of solder contacts, each on a respective one of the third plurality of contact pads.
